(19) United States
(12) Patent Application Publication
(10) Pub. No.: US 2007/0176246 A1
(43) Pub. Date: Aug. 2, 2007

(54) SRAM cells including self-stabilizing transistor structures

(75) Inventors: Frank Wirbeleit, Dresden (DE); Martin Majer, Dresden (DE)

Correspondence Address: MEYERTONS, HOOD, KIVLIN, KOWERT & GOETZEL (AMD), P.O. BOX 398, AUSTIN, TX, 78767-0398, US

(73) Assignee: Advanced Micro Devices, Inc.

(21) Appl. No.: 11/484,295

(22) Filed: Jul. 11, 2006

(30) Foreign Application Priority Data
Jan. 31, 2006 (DE) 10 2006 004 409.6

(51) Int. Cl. H01L 29/76

(52) U.S. Cl. 257/404

(57) ABSTRACT

By providing a self-biasing semiconductor switch, an SRAM cell having a reduced number of individual active components may be realized. In particular embodiments, the self-biasing semiconductor device may be provided in the form of a double channel field effect transistor that allows the formation of an SRAM cell with less than six transistor elements and in preferred embodiments with as few as two individual transistor elements.

### FIELD OF THE PRESENT INVENTION

The present invention generally relates to the fabrication and simulation of integrated circuits, and more particularly to static RAM cells employing transistor architectures that exhibit an extended functionality, thereby providing the potential for simplifying the configuration of the static RAM cells.

### DESCRIPTION OF THE PRIOR ART

In modern integrated circuits such as microprocessors, storage devices, and the like, a huge number of circuit elements, especially transistors, are provided and operated on a restricted chip area. Although immense progress has been made over the recent decades with respect to increased performance and reduced feature sizes of the circuit elements, the ongoing demand for enhanced functionality of electronic devices forces semiconductor manufacturers to steadily reduce the dimensions of the circuit elements and to increase the operating speed thereof. However, the continuing scaling of feature sizes involves great efforts in redesigning process techniques and developing new process strategies and tools so as to comply with new design rules. Generally, in complex circuitry including complex logic portions, the MOS technology is presently a preferred manufacturing technique in view of device performance and/or power consumption. In integrated circuits including logic portions formed by the MOS technology, a large number of field effect transistors (FETs) are provided that are typically operated in a switched mode, that is, these devices exhibit a highly conductive state (on-state) and a high impedance state (off-state). The state of the field effect transistor is controlled by a gate electrode, which may influence, upon application of an appropriate control voltage, the conductivity of a channel region formed between a drain terminal and a source terminal.

FIG. 1a schematically shows a cross-sectional view of a typical field effect transistor element as may be used in modern MOS-based logic circuitry. A transistor element 100 comprises a substrate 101, for instance a silicon substrate having formed thereon or therein a crystalline region 102 on and in which further components of the transistor element 100 are formed. The substrate 101 may also represent an insulating substrate having formed thereon a crystalline semiconductor layer of specified thickness that accommodates further components of the transistor 100. The crystalline region 102 comprises two or more different dopant materials in a varying concentration so as to obtain the desired transistor function. To this end, highly doped drain and source regions 104 defining a first conductivity type, for instance, an n-conductivity, are formed within the crystalline region 102 and have a specified lateral and vertical dopant profile. On the other hand, the crystalline region 102 between the drain and source regions 104 may be doped with a material providing the opposite conductivity type, that is, as in the example shown, a p-conductivity, so as to produce a pn junction with each of the drain and source regions 104. Moreover, a relatively thin channel region 103 may be established between the drain and source regions 104 and it may be doped with a p-type material when the transistor 100 is to represent an n-channel enhancement transistor, or which may be slightly doped with an n-type material when the transistor 100 is to represent an n-channel depletion transistor. Formed above the channel region 103 is a gate electrode 105, which is separated and thus electrically insulated from the channel region 103 by a thin gate insulation layer 106. In a typical modern transistor element, sidewall spacers 107 may be provided at sidewalls at the gate electrode 105, which may be used during the formation of the drain and source regions 104 by ion implantation and/or in subsequent processes for enhancing the conductivity of the gate electrode 105, which is typically comprised of doped polysilicon in silicon based transistor elements. For convenience, any further components such as metal silicides and the like are not shown in FIG. 1a.

As previously mentioned, an appropriate manufacturing process involves a plurality of highly complex process techniques, which depend on the specified design rules that prescribe the critical dimensions of the transistor element 100 and respective process margins. For example, one essential dimension of the transistor 100 is the channel length, i.e., in FIG. 1a the horizontal extension of the channel region 103, wherein the channel length is substantially determined by the dimension of the gate electrode 105 since the gate electrode 105, possibly in combination with any sidewall spacers, such as the spacers 107, is used as an implantation mask during the formation of the drain and source regions 104. As critical dimensions of advanced transistor elements are presently at approximately 50 nm and even less, any further progress in enhancing performance of integrated circuits entails great effort in adapting established process techniques and in developing new process techniques and process tools. Irrespective of the actual dimensions of the transistor element 100, the basic operations scheme is as follows. During operation, the drain and source regions 104 are connected to respective voltages, such as ground and supply voltage VDD, wherein it is now assumed that the channel region 103 is slightly p-doped so as to provide the functionality of an n-channel enhancement transistor. It is further assumed that the left region 104 is connected to ground and will thus be referred to as the source region, even though, in principle, the transistor architecture shown in FIG. 1a is symmetric with respect to the regions 104. Hence, the region 104 on the right hand side, connected to VDD, will be referred to as the drain region. Moreover, the crystalline region 102 is also connected to a specified potential, which may be ground potential and any voltages referred to in the following are considered as voltages with respect to the ground potential supplied to the crystalline region 102 and the source region 104. Without a voltage supplied to the gate electrode 105 or with a negative voltage, the conductivity of the channel region 103 remains extremely low, since at least the pn junction from the channel region 103 to the drain region 104 is inversely biased and only a negligible number of minority charge carriers is present in the channel region 103. Upon increasing the voltage supplied to the gate electrode 105, the number of minority charge carriers, i.e. electrons, in the channel region 103 may be increased due the capacitive coupling of the gate potential to the channel region 102, but without significantly increasing the total conductivity of the channel region 103, as the pn junction is still not sufficiently forward-biased. Upon further increasing the gate voltage, the channel conductivity abruptly increases, as the number of minority charge carriers is increased so as to remove the space charge area in the pn junction, thereby forward-biasing the pn junction so that electrons may flow from the source region to the drain region. The gate voltage at which the abrupt conductivity change of the channel region 103 occurs is referred to as threshold voltage VT.

FIG. 1b qualitatively illustrates the behavior of the device 100 when representing an n-channel enhancement transistor. The gate voltage VG is plotted on the horizontal axis, while the vertical axis represents the current, that is the electrons, flowing from the source region to the drain region via the channel region 103. It should be appreciated that the drain current depends on the applied voltage VDD and the specifics of the transistor 100. At any rate, the drain current may represent the behavior of the channel conductivity, which may be controlled by gate voltage VG. In particular, a high impedance state and a high conductivity state are defined by the threshold voltage VT.

It is noted that similar behaviors are obtained for n-channel depletion, p-channel enhancement and p-channel depletion transistors, which are commonly know in the field of semiconductor physics.

On the basis of field effect transistors, such as the transistor element 100, more complex circuit components may be created. For instance, storage elements in the form of registers, static RAM (random access memory), and dynamic RAM represent an important component of complex logic circuitries. For example, during the operation of complex CPU cores, a large amount of data has to be temporarily stored and retrieved, wherein the operating speed and the capacity of the storage elements significantly influence the overall performance of the CPU. Depending on the memory hierarchy used in a complex integrated circuit, different types of memory elements are used. For instance, registers and static RAM cells are typically used in the CPU core due to their superior access time, while dynamic RAM elements are preferably used as working memory due to the increased bit density compared to registers or static RAM cells. Typically, a dynamic RAM cell comprises a storage capacitor and a single transistor, wherein, however, a complex memory management system is required so as to periodically refresh the charge stored in the storage capacitors, which may otherwise be lost due to unavoidable leakage currents. Although the bit density of DRAM devices may be extremely high, a charge has to be transferred from and to storage capacitors in combination with periodic refresh pulses, thereby rendering these devices less efficient in terms of speed and power consumption when compared to static RAM cells. On the other hand, static RAM cells require a plurality of transistor elements so as to allow the storage of an information bit.

FIG. 1c schematically shows a sketch of a static RAM cell 150 in a configuration as may typically be used in modern integrated circuits. The cell 150 comprises a bit cell 110 including, for instance, two inversely coupled inverters 111. The bit cell 110 may be connectable to a bit line 112 and to an inverse bit line 113 (not shown in FIG. 1c) by respective select transistor elements 114, 115. The bit cell 110, that is, the inverters 111, as well as the select transistor elements 114, 115 may be formed of transistor elements, such as the transistor 100 shown in FIG. 1a. For example, the inverters 111 may each comprise a complementary pair of transistors 100, that is, one p-channel enhancement transistor and one n-channel enhancement transistor coupled as shown in FIG. 1c. Likewise, the select transistor elements 114, 115 may be comprised of n-channel enhancement transistors 100.

During operation of the RAM cell 150, the bit cell 110 may be “programmed” by pre-charging the bit lines 112, 113, for example with logic high and logic zero, respectively, and by activating the select line 116, thereby connecting the bit cell 110 with the bit lines 112, 113. After deactivating the select line 116, the state of the bit cell 110 is maintained as long as the supply voltage is connected to the cell 150 or as long as a new write cycle is performed. The state of the bit cell 110 may be retrieved by, for example, bringing the bit lines 112, 113 in a high impedance state and activating the select line 116.

As is evident from FIG. 1c, high operating speeds are achievable with the cell 150 due to the absence of storage capacitors, and a simplified management in reading and writing the bit cell 110 is provided since any synchronization with refresh pulses is not necessary. On the other hand, at least six individual transistor elements 100 are required for storing an information bit, thereby rendering the architecture of the cell 150 less space efficient. Hence, frequently a trade-off has to be made with respect to bit density in relation to speed and performance requirements.

In view of the problems identified above, a need exists for an improved device architecture that enables the formation of storage elements in a more space efficient manner.

DE 102 45 575 A1 describes a field effect transistor including a dopant island beneath the channel region, the island having an opposite conductivity with respect to the channel region and a carrier density similar to those of the source and drain regions, an a corresponding static RAM cell.

### SUMMARY OF THE INVENTION

Generally, the present invention is directed at techniques that enable the formation and simulation of circuit components including transistor elements in a more space-efficient manner, especially in static memory devices, in that the functionality of a transistor element is extended so that a self-biasing conductive state may be obtained.

According to one illustrative embodiment, a static RAM cell includes a storage transistor element for storing a bit of information. The storage transistor element includes p-doped drain and source regions, both formed in a substantially crystalline semiconductor material, an n-doped and a p-doped channel region located between and adjacent to the drain and source regions, the channel regions further being adjacent to each other, and a gate electrode to enable control of the channel regions. The static RAM cell further includes a supply voltage terminal connecting the source region to a supply voltage source providing power to the static RAM cell, and a conductive region connecting the gate electrode to the supply voltage terminal.

In accordance with another illustrative embodiment, a static RAM cell including first and second storage transistor elements for storing a bit of information is provided. The first storage transistor element includes first drain and source regions formed in a substantially crystalline semiconductor material and n-doped, a first, p-doped and a second, n-doped channel region located between and adjacent to the first drain and source regions and adjacent to each other, and a first gate electrode to enable control of the first and second channel regions. The second storage transistor element includes second drain and source regions formed in the substantially crystalline semiconductor material and p-doped, a third, n-doped and a fourth, p-doped channel region located between and adjacent to the second drain and source regions and adjacent to each other, and a second gate electrode to enable control of the third and fourth channel regions. Further, the static RAM cell includes a conductive region connecting the first source region, the second source region, the first gate electrode and the second gate electrode.

In accordance with yet another embodiment, a computer-readable medium includes computer-executable instructions which, when executed by a computing system, cause the computing system to simulate the behavior of a static RAM cell. Instructions for simulating a field effect transistor having drain, source and gate terminals, instructions for simulating a first voltage controlled switch connected to one of the drain and source terminals, and instructions for simulating a second voltage controlled switch connected to the first switch and to the other of the drain and source terminals are provided.

### BRIEF DESCRIPTION OF THE DRAWINGS

Further advantages, objects and embodiments of the present invention are defined in the appended claims and will become more apparent with the following detailed description when taken with reference to the accompanying drawings, in which:

FIG. 1a schematically shows a cross-sectional view of a typical conventional field effect transistor;

FIG. 1b schematically shows a plot of the progression of the drain current, i.e., the progression of the channel conductivity, versus the applied gate voltage for an n-channel enhancement transistor;

FIG. 1c schematically shows a circuit diagram of a typical conventional static RAM cell including at least six individual transistor elements;

FIG. 2a schematically shows a circuit diagram of a storage element including an n-type self-biasing semiconductor device in accordance with illustrative embodiments of the present invention;

FIG. 2b schematically shows a qualitative plot of the progression of a channel conductivity versus an applied control voltage to obtain a self-biased stationary conductivity state for a storage element as shown in FIG. 2a;

FIG. 2c schematically shows a circuit diagram of a storage element including a p-type self-biasing semiconductor device in accordance with particular embodiments of the present invention;

FIG. 2d schematically shows a qualitative plot of the progression of a channel conductivity versus an applied control voltage to obtain a self-biased stationary conductivity state for the storage element of FIG. 2c;

FIGS. 3a and 3b schematically show cross-sectional views of transistor elements, each having two inversely doped channel regions for an n-type double channel transistor and a p-type double channel transistor, respectively, according to particular embodiments of the present invention;

FIG. 3c schematically illustrates a circuit diagram for a simplified model of a double-channel field effect transistor in accordance with illustrative embodiments of the present invention;

FIG. 3d schematically illustrates a plot of a channel conductivity for each of the two channels in the double channel transistor in a simplified fashion;

FIG. 3e schematically shows a plot qualitatively illustrating the drain currents, i.e., the channel conductivity of the double channel transistor with respect to a variation of the gate voltage according to illustrative embodiments;

FIGS. 4a and 4b schematically show a circuit diagram of a double channel transistor and an equivalent circuit diagram for simulating the double channel transistor, respectively, according to illustrative embodiments of the present invention;

FIGS. 4c and 4d show plots illustrating simulation results for the general work functions of an n-type double channel transistor and a p-type double channel transistor, respectively, according to particular embodiments;

FIG. 5a schematically shows a circuit diagram of a static RAM cell, including an n-type double channel transistor in accordance with a particular embodiment of the present invention, wherein the RAM cell comprises only two transistor elements;

FIG. 5b schematically shows an equivalent circuit diagram for simulating the static RAM cell of FIG. 5a, according to a particular embodiment of the present invention;

FIG. 5c shows a plot illustrating the simulated transient behavior of the circuit shown in FIG. 5d, according to an illustrative embodiment;

FIGS. 5d and 5e are enlarged cutouts of FIG. 5c;

FIG. 6a schematically shows a circuit diagram of a static RAM cell including a p-type double channel transistor in accordance with a particular embodiment of the present invention, wherein the RAM cell comprises only two transistor elements;

FIG. 6b schematically shows an equivalent circuit diagram for simulating the static RAM cell of FIG. 6a, according to an illustrative embodiment;

FIGS. 6c and 6d show plots illustrating the simulated signal behavior and the simulated supply voltage, respectively, of the circuit shown in FIG. 6b, according to an illustrative embodiment;

FIG. 7a schematically shows a circuit diagram of a CMOS static RAM cell including an n-type double channel transistor and a p-type double channel transistor in accordance with a particular embodiment of the present invention, wherein the RAM cell comprises only three transistor elements;

FIG. 7b schematically shows an equivalent circuit diagram for simulating the static RAM cell of FIG. 7a, according to an illustrative embodiment;

FIGS. 7c and 7d show plots illustrating the simulated signal behavior and the simulated supply voltage, respectively, of the circuit shown in FIG. 7b, according to a particular embodiment;

FIG. 8 schematically shows a circuit diagram of an RAM cell including less than six transistor elements in accordance with a further illustrative embodiment;

FIG. 9 schematically shows a cross sectional view of an SOI transistor element having two inversely doped channel regions according to one illustrative embodiments; and

FIG. 10 schematically shows a cross-sectional view of a transistor element having inversely doped channel regions, which also differ in at least one of material composition and internal strain.

### DETAILED DESCRIPTION

While the present invention is described with reference to the embodiments as illustrated in the following detailed description as well as in the drawings, it should be understood that the following detailed description as well as the drawings are not intended to limit the present invention to the particular illustrative embodiments disclosed, but rather the described illustrative embodiments merely exemplify the various aspects of the present invention, the scope of which is defined by the appended claims.

Generally, the present invention is based on the inventors' concept that the circuit architecture of a plurality of logic circuit portions, especially of registers, static memory cells, and the like, may be significantly simplified in that one or more characteristics of a semiconductor switch element may be modified to obtain extended functionality. In particular, the inventors contemplated to provide a self-biasing semiconductor switch, which may be based in particular embodiments of the present invention on a field effect transistor design with a modified channel region, wherein a conductive state, once initiated, is maintained as long as the supply voltage is applied, unless a change of conductivity state is externally initiated. In this way, particularly the number count of individual switch elements in a static RAM cell may be drastically reduced compared to conventional RAM cell designs and may be less than six, thereby enabling the fabrication of fast storage devices with a bit density that is comparable with that of dynamic RAM devices.

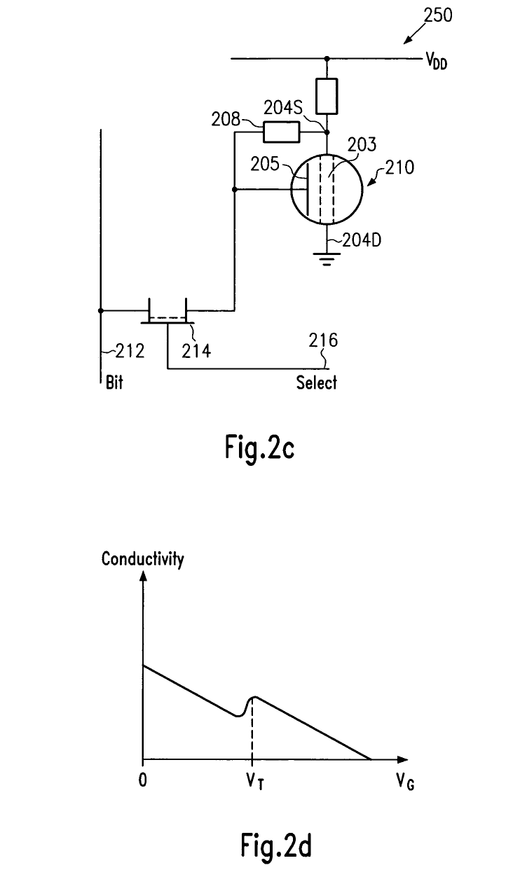

FIG. 2a schematically shows a circuit diagram of a basic static RAM cell 250 comprising a bit cell 210 for storing an information bit. The bit cell 210 is coupled to a select transistor 214, which in turn is connected to a bit line 212 and a select line 216. The bit cell 210 is comprised of a semiconductor element including a channel region 203 that is configured to provide a controllable conductivity, wherein a gate electrode 205 is provided, which enables the control of the channel region 203 via capacitive coupling. Moreover, a feedback section 208 is provided, for instance in the form of an electrically conductive region having a specified resistivity or the like, to connect the channel region 203 via an output terminal 204S with the gate electrode 205. Furthermore, the channel region 203 may be connected to a specified voltage source, such as the source supplying the supply voltage VDD, by a respective output terminal 204D. The bit cell 210 is based on an n-channel enhancement or n-channel depletion transistor element and is configured such that upon application of a specified control voltage to the gate electrode 205, the conductivity of the channel region 203 changes from a moderately high impedance state into a state of moderately high conductivity, which may be maintained, even after interrupting the initial control voltage, via the feedback section 208. To this end, the semiconductor device 210 exhibits a specified behavior with respect to the conductivity of the channel region 203 in relation to the applied control voltage VG once the device 210 is in the conductive state, as will be explained with reference to FIG. 2b.

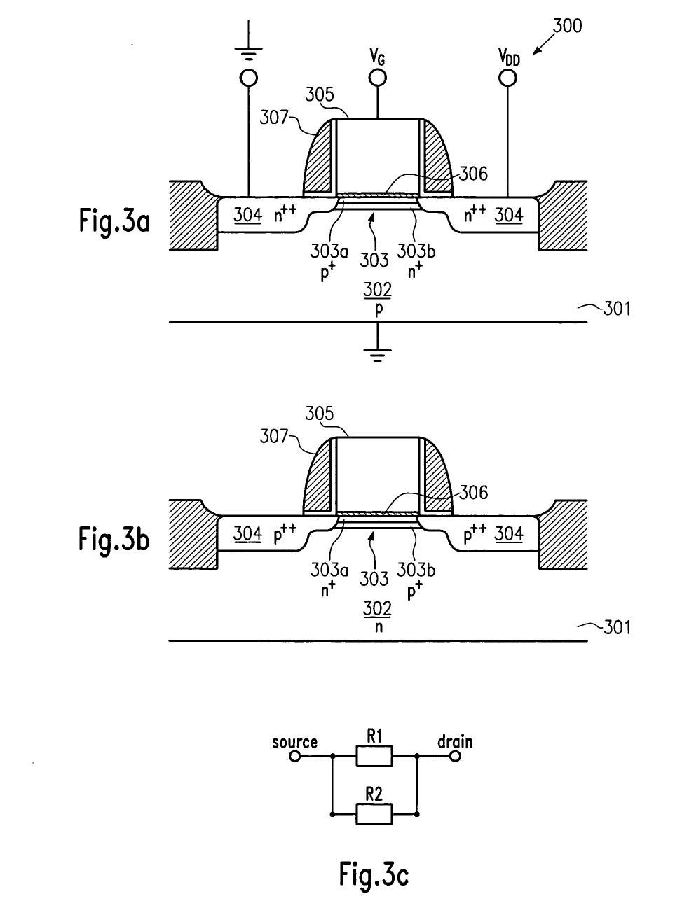

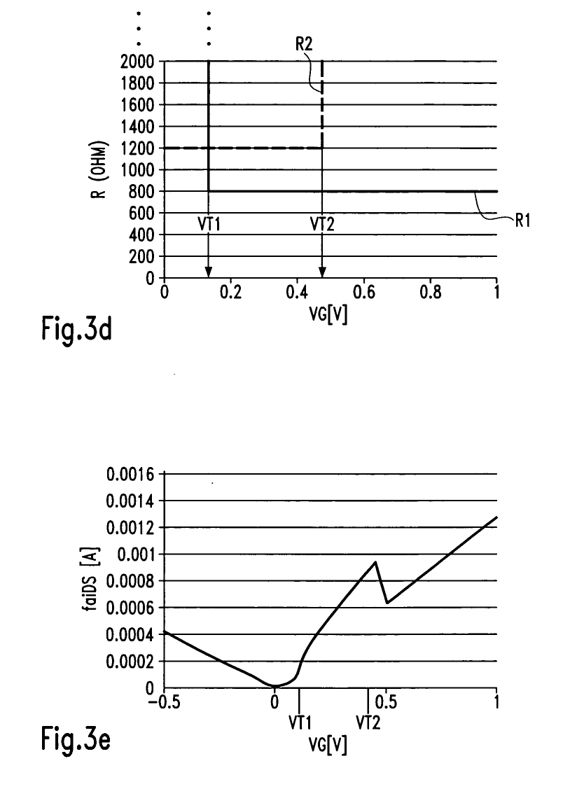

FIG. 2b qualitatively describes the behavior of the bit cell 210 that is obtained by the above-described configuration. In FIG. 2b, the conductivity of the channel 203, which may correspond to the drain source current of the transistor element of the bit cell 210, is plotted along the vertical axis in arbitrary units and the control voltage VG supplied to the gate electrode 205 is shown on the horizontal axis. The semiconductor device 210 is configured such that at a specified threshold voltage VT, which may be set by structural measures as will be described in more detail with reference to FIGS. 3a and 3b and 9 and 10, the conductivity of the channel 203 shows a pronounced abrupt change or, in particular embodiments, a local maximum in such a way that with a further increase of the control voltage VG at the gate electrode 205 a significant drop in conductivity is obtained. In the further description it is assumed that the voltage VDD is higher than the threshold voltage VT. Hence, after application of an initial control voltage in excess of the threshold voltage VT, the channel region 203 is in a highly conductive state so that the supply voltage VDD is more or less also present at the output 204S and, via the feedback section 208, at the gate electrode 205. Thus, even after discontinuing an initial control voltage, a corresponding voltage is supplied via the conductive channel 203, the feedback section 208 to the gate electrode 205, wherein a self-stabilizing condition is established, since the channel conductivity increases as the voltage at the gate electrode 205 tends to decrease during discontinuing the initially supplied control voltage pulse owing to, for example, charge carrier leakage and the like. Consequently, due to the abrupt increase of the conductivity with decreasing voltage at the gate electrode 205 at VT, the voltage drop across the channel 203 is reduced and charge, required at the gate electrode 205 for maintaining the conductivity of the channel 203, is increasingly replaced, thereby maintaining the control voltage VG above or at the threshold voltage VT. As a result, a stationary conductive state of the channel region 203 is achieved and may be maintained as long as the supply voltage VDD is provided. This state will hereinafter also be referred to as self-biased state of the n-type bit cell 210.

Again referring to FIG. 2a, during operation of the static RAM cell 250, the bit cell 210 may be written to by pre-charging the bit line 212 with a voltage above or at the threshold voltage VT, for instance VDD, and by activating the select line 216, also referred to as word line, thereby switching the select transistor 214 from its off-state into its on-state. When the selector transistor 214 is in its on-state, the voltage at the bit line 212 is supplied via the feedback section 208 to the gate electrode 205, which is correspondingly charged so as to generate a conductivity of the channel region 203, as is qualitatively shown in FIG. 2b, at or above the threshold voltage VT. Thereafter, the select transistor 214 may be disabled and the bit line 212 may be brought into a high impedance state so that it is prepared for a read operation. Due to the self-biasing mechanism of the bit cell 210, the conductivity of the channel region 203 is maintained at a moderately high value, even though the initial control voltage pulse supplied via the select transistor 214 is discontinued. As previously explained, this low impedance state of the bit cell 210 is stationary and remains as long as the supply voltage VDD is present or a new write cycle is initiated.

During reading of the bit cell 210, the bit line 212 may be in a high impedance state and the select transistor 214 may be switched into its on-state by activating the select line 216. Due to the self-biased high conductivity state of the bit cell 210, charge may be supplied from the supply voltage source VDD to the bit line 212 so as to establish the voltage VDD at the bit line 212, which may be sensed by a corresponding sense amplifier (not shown). Thus, a logic state corresponding to the self-biased state of the bit cell 210 may be identified and read out. Similarly, a high impedance state may be written into the bit cell 210 by, for instance, pre-charging the bit line 212 with ground potential and activating the select line 216. In this case, the ground potential is supplied to the gate 205 via the feedback section 208,—the inherent resistance of the bit line 212 is assumed to be significantly lower than the resistance of the channel region 203 in its high conductivity state—, and hence the channel region 203 is brought into its high impedance state, which is maintained even if the bit line 212 is decoupled from the output 204S by deactivating the select line 216.

FIG. 2c schematically shows another circuit diagram of a basic static RAM cell 250 comprising a bit cell 210 for storing an information bit. In the embodiment illustrated in FIG. 2c, the bit cell 210 is based on a p-channel depletion transistor element and is coupled to a select transistor 214 which in turn is connected to a bit line 212 and a select line 216. The bit cell 210 is comprised of a semiconductor element including a channel region 203 that is configured to provide a controllable conductivity wherein a gate electrode 205 is provided which enables the control of the channel region 203 via capacitive coupling. Moreover, a feedback section 208 is provided, for instance in the form of an electrically conductive region having a specified resistivity or the like, to connect the channel region 203 via an output terminal 204S with the gate electrode 205. Furthermore, the channel region 203 may be connected with a specified voltage source such as the source supplying the supply voltage VDD via the source terminal 204S. The drain terminal 204D of the bit cell 210 may be grounded. According to the present embodiment, the p-channel depletion bit cell 210 is configured such that upon application of a specified control voltage, e.g., ground potential to the gate electrode 205, the conductivity of the channel region 203 changes from a moderately high impedance state into a state of moderately high conductivity, which may be maintained even after interrupting the initial control voltage, via the feedback section 208. To this end, the semiconductor device 210 exhibits a specified behavior with respect to the conductivity of the channel region in relation to the applied control voltage VG once the device 210 is in the conductive state, as will be explained with reference to FIG. 2d.

FIG. 2d qualitatively describes the behavior of the bit cell 210 of FIG. 2c that is obtained by the above-described configuration. In FIG. 2d, the conductivity of the channel 203, which may correspond to the drain source current of the transistor element of the bit cell 210, is plotted along the vertical axis in arbitrary units and the control voltage VG supplied to the gate electrode 205 is shown on the horizontal axis. The semiconductor device 210 is configured such that at a specified threshold voltage VT, which may be set by structural measures, as will be described in more detail with reference to FIGS. 3a, 3b, 9 and 10, the conductivity of the channel 203 shows a pronounced abrupt change or, in particular embodiments, a local maximum in such a way that with an increase of the control voltage VG at the gate electrode 205 towards the threshold voltage VT, a significant increase in conductivity is obtained. Hence, after application of an initial control voltage lower than the threshold voltage VT, e.g., an initial grounding, the channel region 203 is in a highly conductive state so that the ground voltage is more or less also present at the source terminal 204S and, via the feedback section 208, at the gate electrode 205. Thus, even after discontinuing an initial control voltage, a corresponding voltage is supplied via the conductive channel 203 and the feedback section 208 to the gate electrode 205, wherein a self-stabilizing condition is established, since the channel conductivity increases as the voltage at the gate electrode 205 tends to increase during discontinuing the initially supplied control voltage pulse. Consequently, due to the abrupt increase of the conductivity with increasing voltage at the gate electrode 205 at VT, the voltage drop across the channel 203 is reduced and charge, unwanted at the gate electrode 205 for maintaining the conductivity of the channel 203, is increasingly drawn off, thereby maintaining the control voltage VG below or at the threshold voltage VT. As a result, a stationary conductive state of the channel region 203 is achieved and maintained. This state will hereinafter also be referred to as self-biased state of the p-type bit cell 210.

Again referring to FIG. 2c, during operation of the static RAM cell 250, the bit cell 210 may be written to by pre-charging the bit line 212 with a voltage below or at the threshold voltage VT, for instance ground potential, and by activating the select line (or word line) 216, thereby switching the select transistor 214 from its off-state into its on-state. When the selector transistor 214 is in its on-state, the voltage at the bit line 212 is supplied to the gate electrode 205, which is correspondingly charged so as to generate a conductivity of the channel region 203, as is qualitatively shown in FIG. 2d, at or above the threshold voltage VT. Thereafter, the select transistor 214 may be disabled and the bit line 212 may be brought into a high impedance state so that it is prepared for a read operation. Due to the self-biasing mechanism of the bit cell 210, the conductivity of the channel region 203 is maintained at a moderately high value, even though the initial control voltage pulse supplied via the select transistor 214 is discontinued. As previously explained, this low impedance state of the bit cell 210 is stationary and remains until a new write cycle is initiated.

During reading of the bit cell 210 of FIG. 2c, the bit line 212 may be in a high impedance state and the select transistor 214 may be switched into its on-state by activating the select line 216. Due to the self-biased high conductivity state of the bit cell 210, charge may be drawn from the bit line 212 through the select transistor 214, feedback section 208 and bit cell 210 to ground so as to establish the ground potential at the bit line 212, which may be sensed by a corresponding sense amplifier (not shown). Thus, a logic state corresponding to the self-biased state of the bit cell 210 may be identified and read out. Similarly, a high impedance state may be written into the bit cell 210 by, for instance, pre-charging the bit line 212 with a voltage that is sufficiently high and activating the select line 216. In this case, the high voltage is supplied to the gate 205—the inherent resistance of the bit line 212 is assumed to be significantly lower than the resistance of the channel region 203 in its high conductivity state—and hence the channel region 203 is brought into its high impedance state, which is maintained even if the bit line 212 is decoupled from the output 204S by deactivating the select line 216.

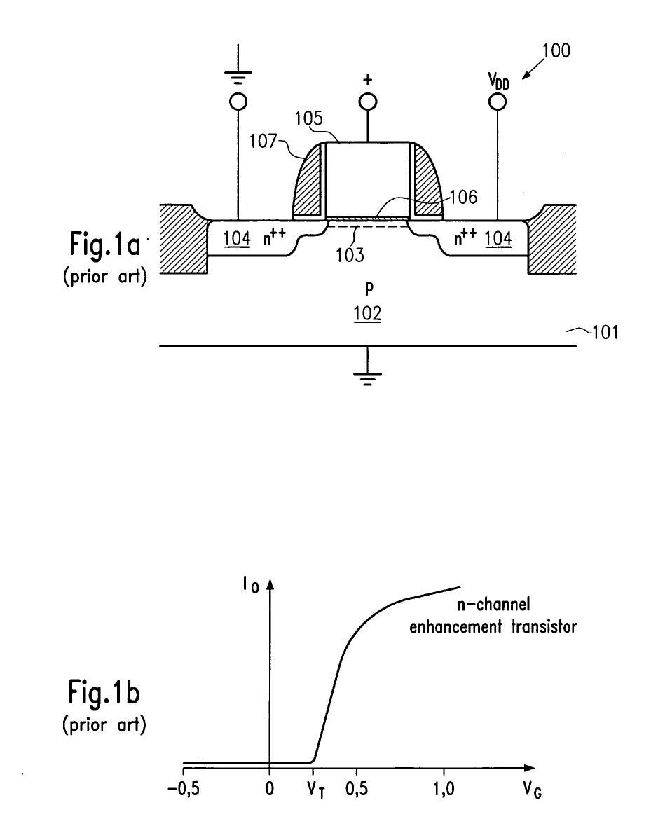

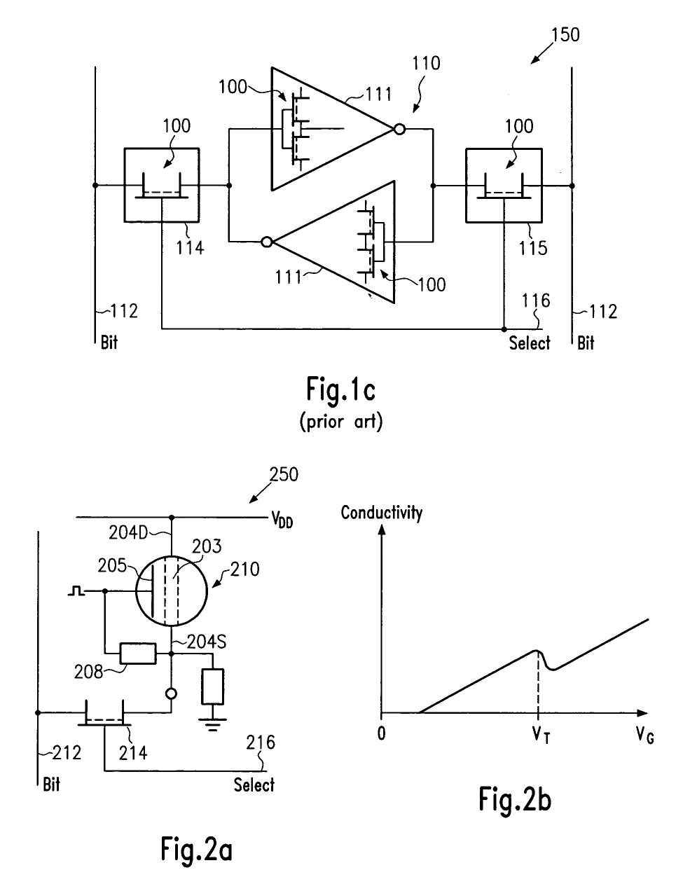

As a result, by means of the semiconductor bit cell 210 a significantly simplified architecture for a static RAM cell is obtained, wherein particularly the number of individual semiconductor elements may be less than in the conventional RAM cell described with reference to FIG. 1c.

FIG. 3a schematically shows a cross-sectional view of a transistor element 300 that may be used in forming a self-biasing semiconductor device, such as the self-biasing bit cell 210 in FIG. 2a. The transistor element 300 comprises a substrate 301, which may be any appropriate substrate such as a bulk semiconductor substrate, an insulating substrate having formed thereon a crystalline semiconductor layer, and the like. In particular embodiments, the substrate 301 may represent a bulk silicon substrate or an SOI (silicon-on-insulator) substrate, since presently and in the near future the vast majority of complex integrated circuits is and will be fabricated on the basis of silicon. It should be appreciated, however, that the principles of the present invention may also be realized on the basis of other semiconductor materials, such as gallium arsenide, germanium, and the like. Formed on the substrate 301 is a substantially crystalline semiconductor region 302, which may comprise a specified dopant material to provide for a specified conductivity type of the region 302. It is noted that substantially crystalline material may comprise, e.g., monocrystals, polycrystals or quasicrystals. Further, crystallographic defects may be present in the material or not. In the embodiment shown in FIG. 3a, the semiconductor region 302 is doped to provide a p-conductivity. Adjacent to the region 302 are formed drain and source regions 304 including a dopant material that imparts an opposite conductivity type to the semiconductor region 302. In the present case, the drain and source regions 304 are heavily doped so that corresponding pn junctions are formed along interfaces between the drain and source regions 304 and the semiconductor region 302. Moreover, a channel region 303 is formed between the drain and source regions 304, wherein, contrary to the conventional transistor design as is explained with reference to FIG. 1a, the channel region 303 is modified in that it defines a specified threshold voltage at which an abrupt conductivity change occurs yet still providing a moderately high conductivity at both sides of the specified threshold voltage.

In one particular embodiment, the channel region 303 may comprise a first channel sub-region 303a that is inversely doped with respect to the drain and source regions 304. Thus, the first channel sub-region 303a may be considered as a “conventional” channel region of a conventional enhancement transistor, such as, for instance, the transistor 100 in FIG. 1a. Additionally, in this particular embodiment, the channel region 303 may further comprise a second channel sub-region 303b that is inversely doped to the first channel sub-region 303, and may therefore be considered as a “depletion” channel. Since the transistor device 300 of FIG. 3a represents an n-type transistor, the first channel sub-region 303a is p-doped and the second channel sub-region 303b is n-doped. It is to be noted that in contrast to insulation islands, the first and second channel regions 303a, 303b may both be electrically active. The transistor element 300 further comprises a gate electrode 305 located so as to enable the control of the first and second channel sub-regions 303a and 303b by capacitive coupling. In the embodiments shown, the gate electrode 305 is separated from the channel region 303 by a gate insulation layer 306 comprised of silicon dioxide and/or silicon nitride and/or silicon oxynitride and/or high-k dielectric materials and the like. Moreover, the transistor element 300 may comprise sidewall spacers 307 formed on sidewalls of the gate electrode 305. It should be appreciated that further components, such as metal silicides, in case the gate electrode 305 and the drain and source regions 304 are substantially comprised of silicon, are not illustrated but may be provided in accordance with design requirements. Furthermore, it is to be noted that other transistor configurations, for instance including raised drain and source regions and the like, may also be employed with the present invention. Moreover, any contact portions that typically provide an electrical connection to the drain and source regions 304 and the gate electrode 305 are not shown. In particular embodiments, a connection may be provided that connects one of the drain and source regions 304 with the gate electrode 305, as is schematically shown in FIG. 2a in the form of the feedback section 208. A corresponding connection may be established in the form of a so-called local interconnect.

FIG. 3b schematically shows the transistor element 300 when configured as a p-type transistor. Hence, the transistor element 300 of FIG. 3b comprises the same components as previously described with reference to FIG. 3a with the exception that the drain and source regions 304, the channel sub-regions 303a and 303b, and the semiconductor region 302 are inversely doped compared to the device of FIG. 3a.

A typical process flow for forming the semiconductor device 300 as shown in FIG. 3a or FIG. 3b may comprise the following processes. After the formation of any isolation structures (not shown) to define the overall dimensions of the transistor 300 and to provide for electrical insulation to neighboring circuit elements, the vertical dopant profile of the semiconductor region 302 may be created by well-established ion implantation cycles. During this ion implantation sequence, also the vertical dopant profile of the channel region 303 may be established. For example, after doping the semiconductor region 302 with a p-type material by ion implantation and/or by providing a pre-doped substrate or by forming an epitaxially grown semiconductor layer in a deposition atmosphere including a dopant, an n-doped region corresponding to the second channel sub-region 303b (FIG. 3a) may be created. For this purpose, a surface portion of the semiconductor region 302 may be pre-amorphized so as to reduce any channeling effects during the ion implantation of the n-type dopant material for defining the second channel sub-region 303b. Thereafter, a further ion implantation sequence may be performed to create the p-doped first channel sub-regions 303a, wherein in both implantation cycles the dose and implantation energy may be appropriately selected so as to achieve a desired concentration and a specified depth within the semiconductor region 302. Corresponding process parameters may readily be obtained by performing simulation calculations and/or test runs. In other embodiments, one or two semiconductor layers may be epitaxially grown in a deposition atmosphere containing the required type of dopant. For instance, an n-type semiconductor layer may be grown on the semiconductor region 302, followed by the epitaxial growth of a p-type semiconductor layer with a desired thickness. Similarly, the semiconductor region 302 may be implanted so as to create the second channel sub-region 303b and subsequently a layer for the first channel sub-region 303a may be formed by epitaxial growth in a dopant-containing atmosphere. Moreover, after forming the channel region 303, additional threshold voltage implantations may be performed so as to correspondingly adjust the finally obtained thresholds for the controllability of the channel region 303 by means of the gate electrode 305. Thereafter, the gate insulation layer 306 and the gate electrode 305 may be formed in conformity with conventionally established processes, followed by advanced implantation cycles for forming the drain and source regions 304. Afterwards, further processes including anneal cycles for activating dopants and re-crystallizing amorphized or damaged crystalline portions in the drain and source regions 304, the semiconductor region 302, and the channel region 303, followed by other processes such as silicidation and the like, may be performed in accordance with well-established process techniques.

The basic operational behavior of the transistor element 300 will now be explained with reference to the n-type transistor of FIG. 3a, wherein corresponding explanations with inverse voltages also apply to the device 300 of FIG. 3b. It is assumed that the region 304 on the left-hand side of FIG. 3a is to represent the source region and is connected to ground potential. Similarly, the semiconductor region 302 is connected to ground potential while the region 304 on the right hand side is connected to the supply voltage VDD so as to act as a drain region. The gate electrode 305 is connected to a voltage source that may provide a control voltage VG. Any values for applied voltages are given with respect to the ground potential, to which the semiconductor region 302 as well as the source region 304 are connected in the example shown. Applying a zero voltage VG may lead to a relatively low conductivity of the channel 303, that is, it may represent a substantially high impedance state of the transistor 300, since the first channel sub-region 303a may be operated below its threshold voltage for providing sufficient minority charge carriers so as to establish a conductive channel, as is previously explained with reference to the enhancement transistor of FIG. 1b. On the other hand, the second channel sub-region 303b forming a pn-junction with the overlying region 303a may donate some of its majority charge carriers to the region 303a, which in turn may provide some of its majority charge carriers to the region 303b until a corresponding space charge area is established. Thus, the second channel sub-region 303b may also form a space charge area with respect to the neighboring drain region 304, wherein this area is inversely biased by VDD and ground potential so as to significantly reduce the conductivity of the second channel sub-region 303b. Consequently, the overall conductance of the channel region 303 is moderately low. Upon increasing the control voltage VG, electrons are increasingly redistributed to the second channel region 303b, thereby increasing the overall conductivity, while the first channel sub-region 303a is still below its threshold value. When the control voltage VG reaches the threshold voltage for the first channel sub-region 303a, which will be referred to as VT1, the conductivity thereof abruptly increases, and hence the overall conductivity of the channel region 303 also abruptly increases. It is further assumed that the second channel sub-region 303b has a second threshold value, referred to in the following as VT2, at which the channel is completely depleted, wherein the corresponding threshold voltage is adjusted to be significantly higher than the first threshold voltage VT1 determining the behavior of the first channel sub-region 303a. Thus, upon further increasing the voltage VG, both channels are conductive, thereby imparting a relatively high conductivity to the entire channel region 303. Upon reaching the second threshold voltage VT2 and thus resulting in the depletion of the second channel sub-region 303b, the overall conductivity abruptly decreased since the current flow is now restricted to the first channel region 303a. Upon further increasing the control voltage VG, the overall conductivity again increases since the conductivity of the first channel region 303a continuously increases while the second channel sub-region 303b is still in a high impedance state.

FIG. 3c schematically shows a simplified electrical model of the transistor element 300 shown in FIG. 3a or 3b. Hereby, it is assumed that the first channel sub-region 303a is represented by a first resistor R1, while the second channel sub-region 303b is represented by a resistor R2. The resistors R1 and R2 may have a resistance value on the order of magnitude of 1000 ohms. Moreover, in this simplified model it is assumed that the resistance value of R1 may take on a high value below the first threshold voltage VT1, which is substantially determined by the structural specifics of the transistor element 300. Similarly, in this model and as explained above, the resistor R2 is assumed to take on a high impedance state when the device 300 is operated with a gate voltage at or above the second threshold voltage VT2, since then the second channel sub-region 303b is substantially completely depleted.

FIG. 3d illustrates the above-explained behavior in a qualitative fashion, wherein the vertical axis represents the resistance values of the resistor's R1 and R2, while the horizontal axis indicates the applied gate voltage VG. As shown in the simplified model, the second channel 303b exhibits a substantially constant ohm-resistance of approximately 1200 ohms at gate voltages below the second threshold voltage VT2, which is approximately 0.45 volts in the present example. Likewise, the first channel region 303a exhibits a high resistance value for gate voltages below the first threshold voltage VT1, which is here selected to approximately 0.15 volts, and abruptly changes to approximately 800 ohm for gate voltages above the first threshold voltage VT1. It should be appreciated that actually the channel conductivity in the low-impedance state varies with the gate voltage, wherein, however, this variation is negligible compared to the abrupt change at the respective threshold voltages VT1 and VT2 and is therefore not shown in FIG. 3d.

FIG. 3e schematically shows a graph representing the current flow through the channel region 303, which may also be considered as representing the conductivity of the channel 303, with a varying gate voltage. For negative gate voltages, the resistor R1 is in its high impedance state, while the resistor R2 is in its low ohmic state, wherein a slight reduction in the conductivity may be observed due to the typical dependence of the drain current from the gate voltage, i.e., the number of free charge carriers is determined by the gate potential and thus leads to a typical variation of the channel conductivity and hence of the channel resistance, which is not taken into consideration in the model shown in FIG. 3d since the variation of the resistance in the on-state is significantly less compared to the difference between the high impedance state and the high conductivity state. At a gate voltage of approximately 0, the total conductivity has a minimum, as previously explained, and slightly increases for positive gate voltages until the threshold VT1 is reached, which causes an abrupt change in conductivity. Thereafter, both resistances R1 and R2 are in their low-ohmic state and the drain currents, and thus the conductivity, increases with increasing gate voltage mainly due to the variation of the first channel resistance. At the second threshold voltage VT2, the second channel is depleted and hence the total drain current, and thus the total conductivity of the channel 303, is abruptly decreased and starts increasing from a lower level with increasing gate voltage due to the ongoing increase in conductivity of the first channel region 303a. Consequently, the transistor elements 300 exhibit a behavior of the channel conductivity as is explained with reference to FIG. 2b, thereby enabling the formation of a semiconductor device, such as the bit cell 210 of FIG. 2a, on the basis of conventional transistor technologies with a modification of the channel region, as is described, for instance, with reference to the channel region 303.

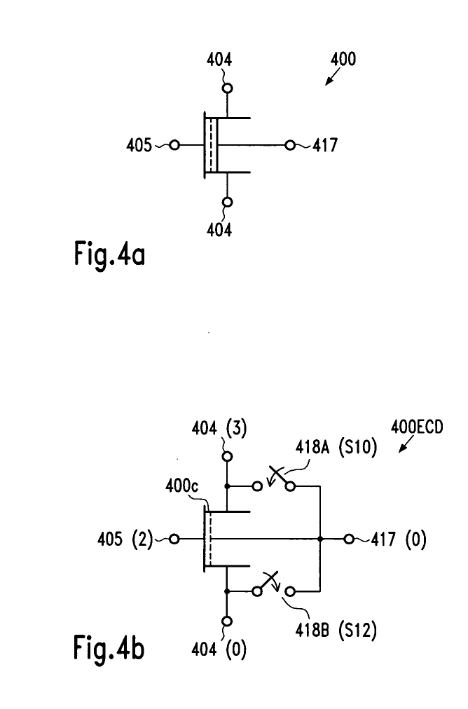

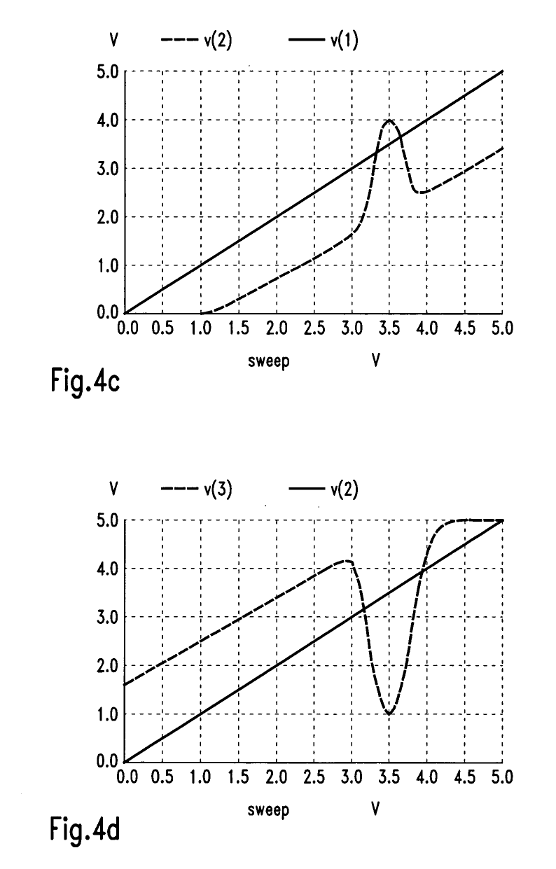

FIG. 4a shows a schematic circuit diagram including a circuit symbol for a modified transistor element 400 according to an embodiment of the present invention. The transistor element 400 has a modified channel region, e.g. in the form of a double channel region as discussed with reference to FIGS. 3a, 3b, 9 and 10 and is connectable via a gate electrode 405 and drain/source terminals 404. Further, a substrate connector 417 for electrically coupling to the transistor substrate (for instance substrate 301, 901 and 1001 in FIGS. 3a, 3b, 9 and 10, respectively) is provided.

To investigate the behavior of the transistor element 400 of FIG. 4a, the transistor 400 may be implemented in computer circuit simulation software including instructions for simulating one ore more of the components of FIG. 4b. To this end, any appropriate general purpose analog circuit simulator, e.g., the SPICE (Simulation Program for Integrated Circuits Emphasis) simulator may be used. In the particular embodiments, the transistor element 400 is simulated in WIN-SPICE, version 1.05.01 (Windows).

FIG. 4b shows an equivalent circuit diagram 400ECD for simulating the transistor element 400 according to the present embodiment. In this particular embodiment, the transistor element 400 having the above-discussed modified channel region is replaced with a conventional field effect transistor 400c. A switch 418A is introduced between one of the drain/source terminals 404 and the substrate connector 417. Similarly, another switch 418B is connected between the other of the drain/source terminals 404 and the substrate connector 417. For implementing the equivalent circuit diagram 400ECD of the transistor element 400 in the SPICE simulator, two voltage controlled switches with a smooth on-off transition, referred to as VSWITCHES, are used for the switches 418A and 418B. According to the present embodiment, the implementation of the transistor element 400 is achieved through the following SPICE simulation script wherein the nomenclature of the circuit elements and terminals refers to the bracketed reference signs in FIG. 4b.

| | | | | | |
|---|---|---|---|---|---|
| m1 | 3 | 2 | 1 | 0 | modn |
| S10 | 3 | 5 | 2 | 0 | SMOD10 |
| S11 | 5 | 1 | 2 | 0 | SMOD11 |

MODEL SMOD10 VSWITCH(RON = 20k ROFF = 2e6k VON = 4 VOFF = 2)
MODEL SMOD11 VSWITCH(RON = 2e6k ROFF = 20k VON = 5 VOFF = 3)

FIGS. 4c and 4d show simulation results for an n-type transistor element 400 and a p-type transistor element 400, respectively, according to a particular embodiment. In both FIGS. 4c and 4d, the development of a gate and a source voltage against a sweep voltage, representing, e.g., a time axis is shown. In FIG. 4c, the input voltage v(2), i.e., the voltage between terminals 2 and 0 of FIG. 4b linearly increases with the sweep voltage. Thus, the horizontal axis of the plots may also be interpreted as representing the gate voltage applied to the simulated transistor element 400. In FIG. 4d, however, the horizontal axis of the plots may rather be seen as representing an offset gate voltage, due to the different polarity of the p-type transistor element 400. Particularly, a sweep voltage of 5.0V in FIG. 4d may correspond to a gate voltage of 0V, and sweep voltages of 4.5V and 3.5V may correspond to gate voltages of −0.5V and −1.5V, respectively.

As can be seen from FIG. 4c, the source voltage v(1), i.e., the voltage between terminals 1 and 0 of FIG. 4b reveals a first threshold voltage VT1, as discussed above with reference to FIGS. 3a to 3e, at a gate voltage of 1.0V. At 3.5V gate voltage, the source voltage reaches a peak and then abruptly decreases and starts re-increasing from a lower level with increasing gate voltage. Thus, the gate voltage of 3.5V at the source voltage peak may be interpreted as a second threshold voltage VT, VT2, as discussed above and the abruptly falling edge may allow the transistor element 400 to be in the self-biased state.

Similarly, as apparent from the simulated behavior of the source voltage v(3), i.e., the voltage between terminals 3 and 0 of FIG. 4b depicted in FIG. 4d, the p-type transistor element 400 is implemented in the present embodiment with a pinch-off value of −0.5V and a self-biased state at −1.5V gate voltage. Again, the source voltage reveals an abrupt decrease which enables the self-biased state of the transistor element 400.

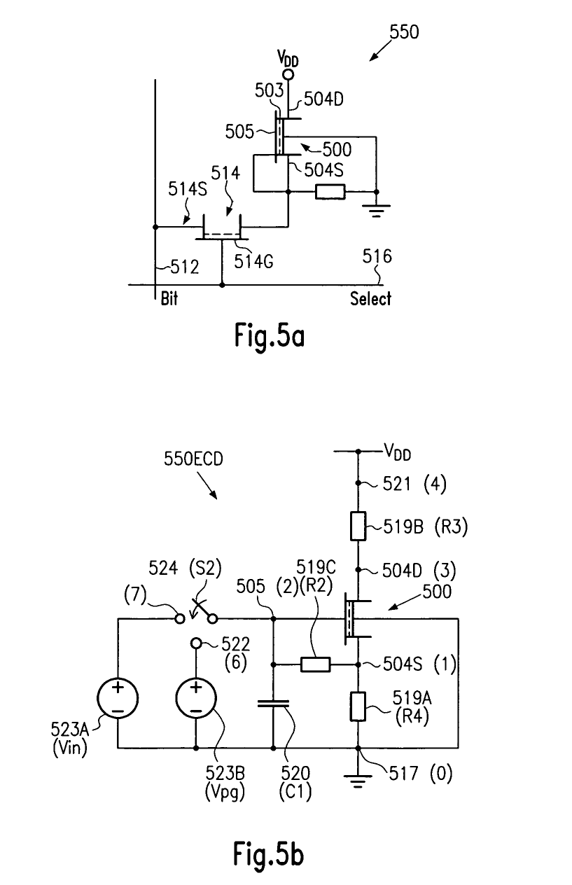

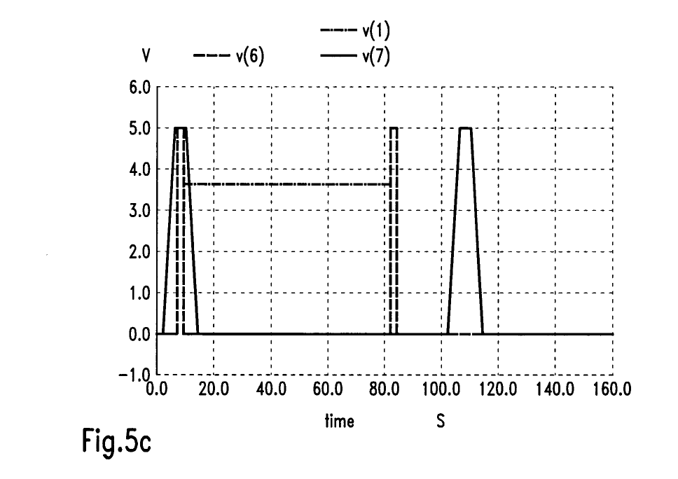

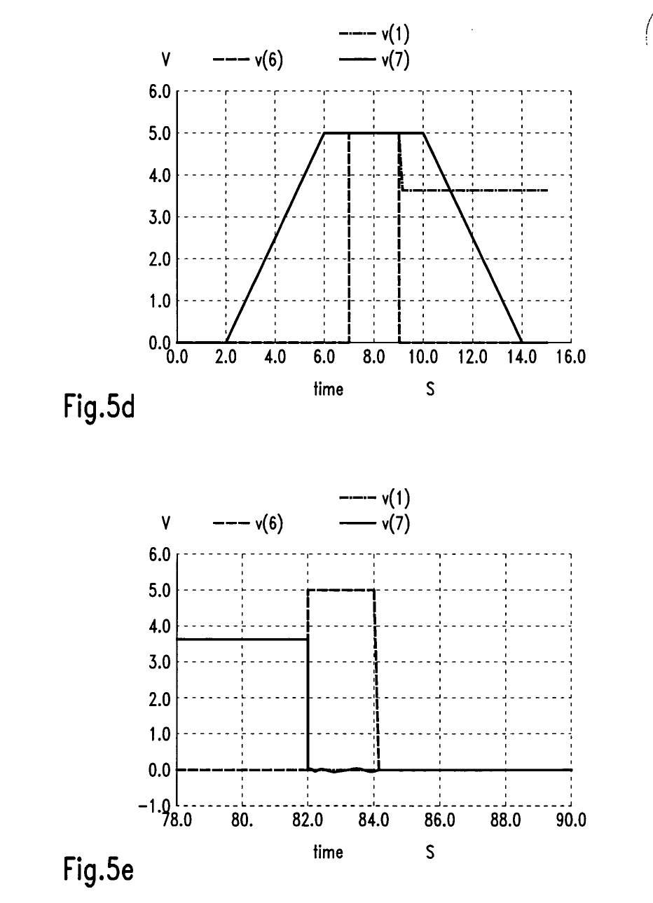

FIG. 5a schematically shows a circuit diagram of an SRAM cell 550 including a transistor element having a modified channel region so as to store a bit of information. The cell 550 comprises an n-type transistor element 500 having a modified channel region 503 that may include a first channel region and a second channel region, as is shown, for instance, in FIGS. 3a and 3b. Moreover, the transistor element 500 comprises a gate electrode 505 and a drain terminal 504D and a source terminal 504S. FIG. 5a also illustrates the circuit symbol introduced above with reference to FIG. 4a for a field effect transistor having a modified channel configuration that provides for the above-described characteristic and which may in particular embodiments provided as a double channel configuration. Moreover, the gate electrode 505 and the source terminal 504S are electrically connected and are both connected to a select transistor 514, the gate 514G of which is connected to a select line 516 while a source/drain terminal 514S is connected to a bit line 512. In one particular embodiment, the SRAM cell 550 merely includes the transistor elements 514 and 500 as the only transistor elements and does not require any further active components. In other embodiments, further transistor elements may be provided to enhance the functionality and/or the reliability of the cell 550 as will be described later on. It is to be noted, however, that the total number of transistor elements may still be less than six transistor elements, as in the conventional design shown in FIG. 1c. It should be appreciated that the transistor elements 500 and 514 may be readily formed in accordance with the process flow as previously described with reference to FIGS. 3a and 3b, wherein any additional process steps for forming the modified channel region 503 may be performed, for instance by ion implantation, while the transistor 514 is masked so that a high degree of compatibility is still maintained for the entire process flow for forming the cell 550.

The operation of the cell 550 is substantially the same as is previously described with reference to FIGS. 2a and 2b. That is, when writing a logic 1 state into the cell 550, that is, into the transistor element 500, the bit line 512 may be pre-charged and the select transistor 514 may be turned on by activating the select line 516. Hereby, the gate 505 is set to the potential of the bit line 512, which is assumed to be VDD that, in turn, is higher than the specified threshold voltage, at which the conductivity of the channel region 503 has a local maximum. For convenience, the specified threshold voltage may be referred to as VT2, as shown in FIGS. 3e and 3d. As a result of the application of VDD at the gate electrode 505, the channel conductivity is in its low impedance state, but is located at the right side of the threshold value VT2 (cf. FIG. 3e). After disconnecting the transistor element 500 from the pre-charged bit line 512 by deactivating the select line 516, the high conductivity state is maintained since now the transistor element 500 is in a self-biased stationary state, which leads to an increase of conductivity whenever the gate voltage tends to drop. As a result, the source terminal 504S is maintained at a voltage at or above the threshold voltage VT2, thereby indicating a logic high state. This state may be read out in the same way as is described with reference to FIG. 2a. Similarly, a high impedance state may be written into the cell 550 by correspondingly pre-charging the bit line 512 and activating the select line 516. In this case, the conductivity of the channel region 503 is low and remains low unless a new state is written into the cell 550.

In order to demonstrate the application of the transistor element 500 having the modified channel region 503 in a static RAM cell, the circuit 550ECD shown in FIG. 5b was simulated in an embodiment. To this end, there may be provided a computer program including instructions for simulating at least one of the components of FIG. 5b. The circuit 550ECD represents an equivalent circuit diagram of the SRAM cell 550, for simulation purposes. According to the present embodiment, a shunt resistor 519A is introduced between the source terminal 504S and the substrate connector 417. Additionally, resistors 519B, 519C are introduced between the source terminal 504S and the gate electrode 505 and between the drain terminal 504D and the voltage supply VDD, respectively, to simulate electrical wires and to create nodes for investigating the transmission behavior of the transistor element 500. In the embodiment shown in FIG. 5b, the shunt resistor 519A has a resistance of R4=1MΩ, the resistor 519B has a resistance of R3=1 μΩ and the resistance of resistor 519C is R2=1Ω. However, in other embodiments, other resistances may be employed. The resistor element 500 itself may be simulated using the equivalent circuit diagram 400ECD and SPICE script discussed above with reference to FIG. 4b. To simulate the dynamic behavior of the transistor element 500 in the SRAM cell 550, a pulsed signal source 523A and a pass gate signal source 523B are included into the simulation of the present embodiment. The signal source 523A provides a voltage signal Vin for simulating the signal on the bit line 512 and the signal source 523B provides a signal Vpg for simulating the signal on the select line 516. The select transistor 514 of the SRAM cell 550 is simulated by the switch 524 of the equivalent circuit diagram 550ECD. Further, for simulation purposes a parasitic capacitor 520 is introduced as well which may represent an input capacity of the simulated transistor element 500. The simulation of the present embodiment uses a DC 5V power source for the VDD supply. In the simulation, the voltage between the gate electrode 505 (node 2) and the substrate connector 517 (node 0) is the input signal and the voltage between the source terminal 504S (node 1) and the substrate connector 517 is the output signal. By coupling the input and output signals, the self-biasing behavior of the transistor element 500 can be used to give the SRAM cell circuit 550ECD a self stabilizing property, as discussed above with reference to FIG. 5a. In accordance with a particular embodiment, the equivalent circuit diagram 550ECD is simulated using the following script implemented in WIN-SPICE Version 1.05.01 (Windows). Thereby the elements of the equivalent circuit diagram 550ECD are referred to by the bracketed reference signs shown in FIG. 5b. In other embodiments, different simulation software may be used.

*-- S_NMOS_Cell --
Vdd 4 0 5v
Vpg 6 0 PULSE(0 5 7S 2nS 2nS 2S 75S)
Vin 7 0 PULSE(0 5 2S 4S 4S 4S 100S)
R2 2 1 1
R3 4 3 1e−6
R4 1 0 1e6
*-------------------
m1 3 2 1 0 modn
C1 2 0 cap1 0.3u
S10 3 5 2 0 SMOD10
S11 5 1 2 0 SMOD11
*-------------------
S2 7 2 6 0 SMOD2 OFF
*--------------------
.MODEL SMOD10 VSWITCH(RON=20k ROFF=2e6k VON=4 VOFF=2)
.MODEL SMOD11 VSWITCH(RON=2e6k ROFF=20k VON=5 VOFF=3)
.MODEL SMOD2 SW RON=1 ROFF=10e8 VT=4 VH=0.01
.model modn nmos VTO=1
.MODEL cap1 C
.dc vin 0 5 .1
.end

FIG. 5c shows the transient behavior of the circuit 550ECD of FIG. 5b resulting from the simulation of the present embodiment. The Figure shows the overall simulation of the word line signal v(6) between nodes 6 and 0 of FIG. 5b, the bit line signal v(7) between nodes 7 and 0, and the SRAM cell status v(1) between nodes 1 and 0 for a full cycle of writing a logic high signal into the SRAM cell 550, storing the logic high signal, writing a logic low signal into the SRAM cell 550, and storing the logic low signal. FIGS. 5d and 5e are enlarged views of FIG. 5c at the logic high writing cycle and logic low writing cycle, respectively. The Figures illustrate the stabilization of the SRAM cell 550 at the self-biased state of the transistor element 500 for logic high signals. According to the present embodiment, logic low signals correspond to 0V and logical high signals to the self-biasing state voltage of 3.5V of the transistor element 500.

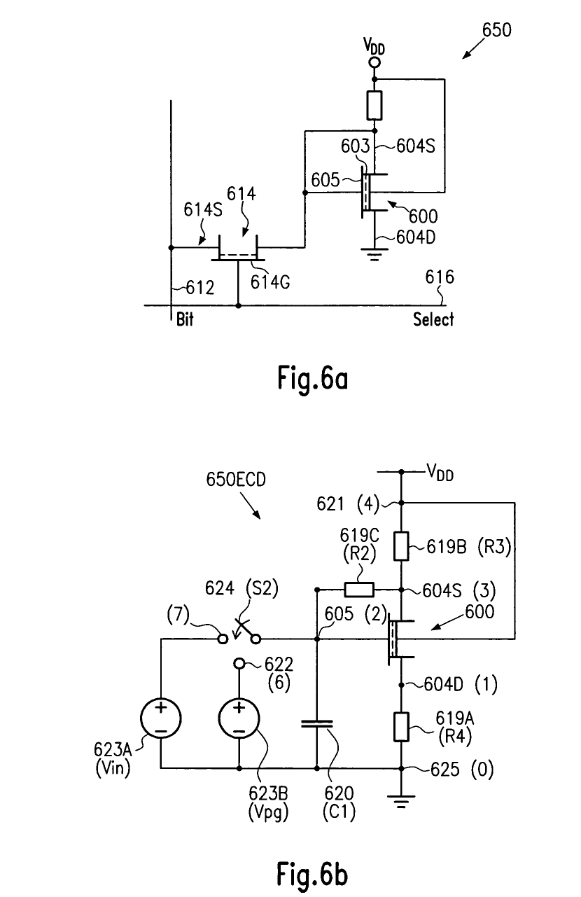

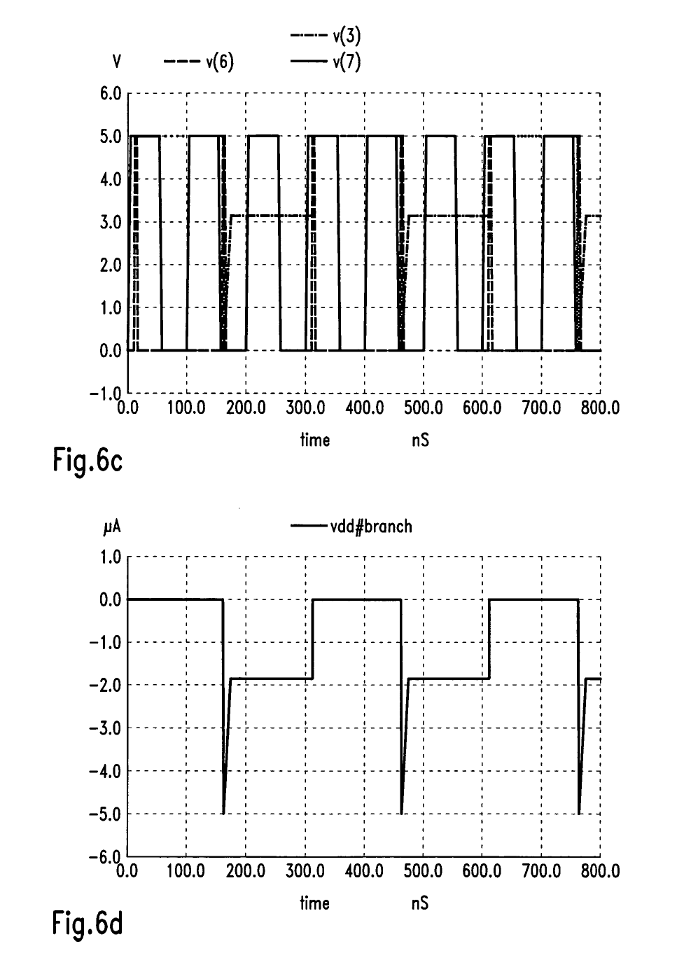

FIG. 6a schematically shows a circuit diagram of an SRAM cell 650 including a transistor element 600 having a modified channel region so as to store a bit of information. The cell 650 comprises a p-type transistor element 600 having a modified channel region 603 that may include a first channel region and a second channel region as shown for instance in FIG. 3b and may in particular embodiments be provided as a double channel configuration. Moreover, the gate electrode 605 and the source terminal 604S are electrically connected and are both connected to a select transistor 614, the gate 614G of which is connected to a select line 616 while a source/drain terminal 614S is connected to a bit line 612. In one particular embodiment, the SRAM cell 650 merely includes the transistor elements 614 and 600 as the only transistor elements and does not require any further active components. In other embodiments, further transistor elements may be provided to enhance the functionality and/or the reliability of the cell 650. The total number of transistor elements may however still be less than six transistor elements, as in the conventional design shown in FIG. 1c. It should be appreciated that the transistor elements 600 and 614 may be readily formed in accordance with the process flow as previously described with reference to FIGS. 3a and 3b, wherein any additional process steps for forming the modified channel region 603 may be performed, for instance by ion implantation, while the transistor 614 is masked so that a high degree of compatibility is still maintained for the entire process flow for forming the cell 650.

The operation of the cell 650 is substantially the same as is previously described with reference to FIGS. 2c and 2d. That is, when writing a logic 0 state into the cell 650, that is, into the transistor element 600, the bit line 612 may be pre-charged at a sufficiently low voltage, e.g., ground potential and the select transistor 614 may be turned on by activating the select line 616. Hereby, the gate 605 is set to the potential of the bit line 612, thus to a potential lower than the specified threshold voltage, at which the conductivity of the channel region 603 has a local maximum. For convenience, the specified threshold voltage is in the following referred to as VT, in accordance with FIG. 2d. As a result of the application of the ground potential at the gate electrode 605, the channel conductivity is in its low impedance state, but is located at the left side of the threshold value VT (cf. FIG. 2d). After disconnecting the transistor element 600 from the bit line 612 by deactivating the select line 616, the high conductivity state is maintained since now the transistor element 600 is in a self-biased stationary state, which leads to an increase in conductivity whenever the gate voltage tends to increase. As a result, the source terminal 605s is maintained at a voltage at or below the threshold voltage VT, thereby indicating a logic low state. This state may be read out in the same way as is described with reference to FIG. 2c. Similarly, a high impedance state may be written into the cell 650 by correspondingly pre-charging the bit line 612 and activating the select line 616. In this case, the conductivity of the channel region 603 is low and remains low unless a new state is written into the cell 650.

In order to demonstrate the application of the p-type transistor element 600 in the SRAM cell 650, the equivalent circuit diagram shown in FIG. 6b is simulated according to an embodiment. In this simulation, additional resistors 619A and 619C are introduced to simulate electrical wires and to create nodes for the transition behavior of the transistor element 600, similarly to the simulation described above with reference to FIG. 5b. Also, a shunt resistor 619B is introduced which is now located between the source terminal 604S and the voltage supply providing the VDD voltage, due to the different polarity of the p-type transistor element 600. According to the present embodiment, the simulation uses a shunt resistor of R3=1MΩ. The resistances of the resistors 619A and 619C may be R4=1 kΩ and R2=1 kΩ, respectively. However, in other embodiments, other resistance values may be applied. The bit line and word line signals and the select transistor of the SRAM cell 650 may be simulated in the same way as explained above with reference to FIG. 5b, i.e., by the voltage sources 623A, 623B and the switch 624, respectively. The behavior of the transistor element 600 may be simulated on the basis of the equivalent circuit diagram 400ECD and simulation script discussed above with regard to FIG. 4b. According to the present embodiment, the simulation is achieved through the following script implemented in WIN-SPICE Version 1.05.01 (Windows) wherein the nodes and elements of the equivalent circuit diagram 650ECD are referred to by the bracketed reference numerals indicated in FIG. 6b. In other embodiments, the SRAM cell 650 may be simulated based on other simulation software including instructions for simulating one or more of the components shown in FIG. 6b.

* S_PMOS_DCT_Cell
vdd 4 0 5v
Vpg 6 0 PULSE(0 5 10NS 2NS 2NS 2NS 150NS)
Vin 7 0 PULSE(0 5 2NS 2NS 2NS 50NS 100NS)
R2 2 3 1k
R3 4 3 1000k
R4 1 0 1k
* -------------------
m1 3 2 1 3 modp
C1 2 0 cap1 10f
S10 3 5 2 0 SMOD10
S11 5 1 2 0 SMOD11
* -------------------
S2 7 2 6 0 SMOD2 OFF
*--------------------
.MODEL SMOD10 VSWITCH(RON=20k ROFF=2e6k VON=4 VOFF=2)
.MODEL SMOD11 VSWITCH(RON=2e6k ROFF=20k VON=5 VOFF=3)
.MODEL SMOD2 SW RON=1k ROFF=1e12k VT=4.5 VH=0.1
model modp pmos VTO=−1
.MODEL cap1 C
.dc vin 0 5 .1
.end

FIG. 6c illustrates a number of read-store-write cycles of the SRAM cell 650, as simulated according to the present embodiment. Specifically, the simulated behavior of the word line signal v(6), i.e., the voltage between nodes 6 and 0 of FIG. 6b, the bit line signal v(7) between nodes 7 and 0, and the voltage signal v(3) between nodes 3 and 0 representing the SRAM cell status are depicted.

FIG. 6d shows the current in the branch connected to the VDD voltage source of the SRAM cell 650 as simulated according to the present embodiment. As can be seen from FIG. 6d, the SRAM cell 650 of the present embodiment causes a relatively high power consumption. Generally the power consumption can be reduced by using higher shunt resistances and optimized transistor architectures. Thus, particularly for small capacity SRAM implementations, the SRAM cells 550, 650 described with reference to FIGS. 5a to 6d may be used for providing SRAM functionality on very small chip areas, thereby minimizing the power consumption using the generally known techniques.

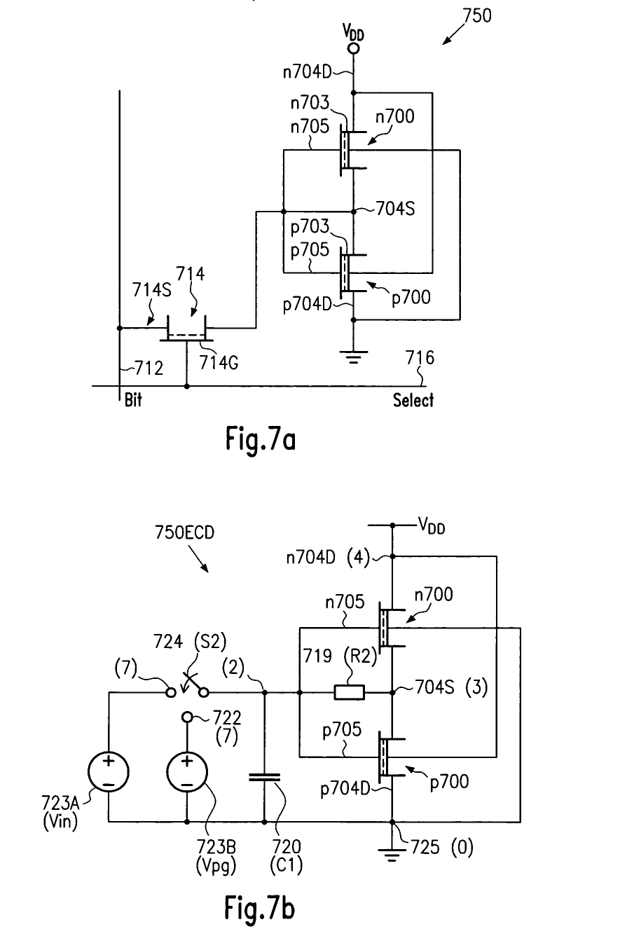

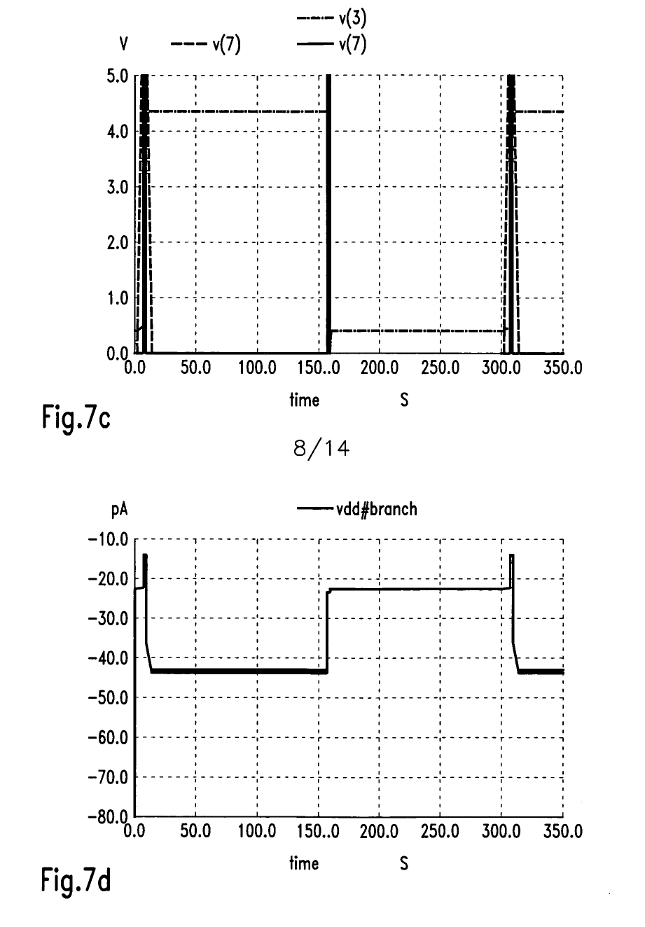

FIG. 7a schematically shows a circuit diagram of a CMOS SRAM cell 750 including an n-type transistor element n700 and a p-type transistor element p700 both having a modified channel region so as to store a bit of information. The transistor element n700 has a modified channel region n703 that may include a first channel region and a second channel region as shown for instance in FIG. 3a. Similarly, the transistor element p700 includes a modified channel region p703 which may in turn include a first channel region and a second channel region, as shown, e.g., in FIG. 3b. Moreover, the transistor elements n700 and p700 each comprise a gate electrode n705, p705, a drain terminal n704D, p704D and a source terminal. According to the embodiment shown in FIG. 7a, the source terminals of the transistor elements n700, p700 are electrically connected together in node 700s. Further, the source terminals are electrically connected to each of the gate electrodes n705, p705 and to a select transistor 714, the gate 714G of which is connected to a select line (or word line) 716 while a source/drain terminal 714S is connected to a bit line 712. In the particular embodiment of FIG. 7a, the SRAM cell 750 merely includes the transistor elements 714, n700 and p700 as the only transistor elements and does not require any further active components. In other embodiments, further transistor elements may be provided to enhance the functionality and/or reliability of the cell 750. However, the total number of transistor elements may still be less than six transistor elements, as in the conventional design shown in FIG. 1c. It should be appreciated that the transistor elements n700, p700 and 714 may be readily formed in accordance with the process flow as previously described with reference to FIGS. 3a and 3b, wherein any additional process steps for forming the modified channel regions n703, p703 may be performed, for instance by ion implantation, while the transistor 714 is masked so that a high degree of compatibility is still maintained for the entire process flow for forming the cell 750.

The operation of the n-type transistor element n700 is substantially the same as is previously described with reference to FIGS. 2a, 2b and 5a. Similarly, the p-type transistor element p700 substantially behaves in the same way as discussed above with regard to FIGS. 2c, 2d and 6a. Thus, once a logic state has been written into the transistor elements n700, p700, it is maintained even if the bit line 712 is decoupled from the transistor elements n700, p700 by deactivating the select line 716. As a result, by means of the semiconductor bit cells n700, p700, the architecture for a static RAM cell is obtained wherein particularly the number of individual semiconductor elements may be less than in the conventional RAM cell described with reference to FIG. 1c.

FIG. 7b illustrates an equivalent circuit diagram 750ECD for simulating the behavior of the CMOS SRAM cell 750 according to an embodiment. Each of the transistor elements n700, p700 may be simulated using the equivalent circuit diagram 400ECD shown in FIG. 4b. Similarly to the simulations discussed above with reference to FIGS. 5b and 6b, the bit line and word line signals are simulated by Vin and Vpg voltages provided by voltage sources 723A and 723B, respectively. The select transistor 714 is simulated by the switch 724. Further, a resistor 719 is provided between the node 704S connecting the source terminals and the node connecting the gate electrodes n705, p705 to the switch 724. Further, a parasitic capacitor 720 is provided between the switch 724 and the drain terminal p704D. The behavior of the equivalent circuit diagram 750 is simulated in the present embodiment using the following script implemented in WIN-SPICE Version 1.05.01 (Windows). Thereby the nodes and elements of the equivalent circuit diagram 750ECD are denoted using reference numerals indicated in brackets in FIG. 7e. In other embodiments, instructions for simulating at least one of the components of FIG. 7b may be provided using different simulation software.

* S_CMOS_DCT_Cell
vdd 4 0 5v
vpg 6 0 PULSE(0 5 7S 2nS 2nS 2S 150S)
Vin 7 0 PULSE(0 5 2S 4S 4S 4S 300S)
R2 2 3 1
R4 1 0 1e−6
*--------------------
m1 4 2 3 0 modn
S10 4 5 2 0 SMOD10n
S11 5 3 2 0 SMOD11n
*--------------------
m1 3 2 1 4 modp
S10 3 8 2 0 SMOD10p
S11 8 1 2 0 SMOD11p
*--------------------
C1 2 0 cap1p 1p
S2 7 2 6 0 SMOD2 OFF
*--------------------
.MODEL cap1p C
.MODEL SMOD10n VSWITCH(RON=20k ROFF=2e9k VON=4
VOFF=2)
.MODEL SMOD11n VSWITCH(RON=2e9k ROFF=20k VON=5
VOFF=3)
.MODEL SMOD10p VSWITCH(RON=20k ROFF=2e9k VON=4
VOFF=−1)
.MODEL SMOD11p VSWITCH(RON=2e9k ROFF=20k VON=5
VOFF=2)
.MODEL SMOD2 SW RON=1 ROFF=1e12 VT=4 VH=0.1
.model modn nmos VTO=1
.model modp pmos VTO=−1
.dc vin 0 5 .1
.end

As can be seen from the above SPICE script, the VSWITCH voltages are set different from each other for SMOD10n/11n and SMOD1p/11p in order to adjust the points at which the transistor elements n700, p700 enter their self-biased stationary state. Thereby different levels for internal high and low states can be set up.

FIG. 7c illustrates the behavior of the CMOS SRAM cell 750 in the simulation described with reference to FIG. 7b. FIG. 7c shows the word line signal v(6) between nodes 6 and 0 of FIG. 7b, the bit line signal v(7) between nodes 7 and 0, and the SRAM cell status v(3) between nodes 3 and 0 during multiple write-store-read cycles. As can be seen from FIG. 7c, the internal high and low states appear at different levels due to the different VSWITCH voltages used in the simulation, as indicated above.

In FIG. 7d, the current in the VDD branch and thus the power consumption of the CMOS SRAM cell 750 resulting from the simulation of the equivalent circuit diagram 750ECD according to the present embodiment is shown. When comparing FIG. 7d to the power consumption shown in FIG. 6d of the SRAM cell 650, it can be seen that the CMOS SRAM cell 750 of the present embodiment is significantly less power consuming. Therefore, the CMOS SRAM cell 750 allows a cost efficient integration of immense SRAM capacities of, e.g., some GBytes into SRAM devices and microprocessors while keeping the power consumption at a low level.

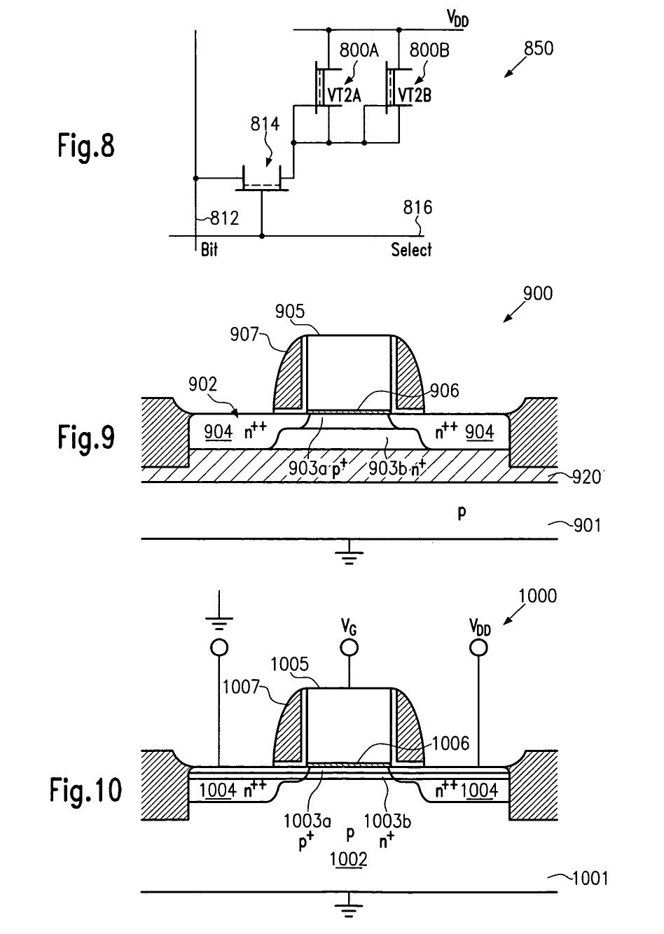

FIG. 8 schematically shows a circuit diagram describing an SRAM cell 850 similar to the SRAM cell 550 discussed above with reference to FIG. 5a, now containing more than two transistor elements, but less than six transistor elements. In this embodiment, a first double channel transistor element 800A and a second double channel transistor element 800B are provided, which may differ from each other by a different threshold voltage VT2a and VT2b. A corresponding arrangement may be advantageous in operating the cell 850 with two different supply voltages VDD, wherein a first operating mode may be considered as a low current mode with a reduced supply voltage and possibly reduced operating speed, while a high current mode may allow the operation with an increased supply voltage, thereby possibly improving the total operating speed and/or the signal to noise ratio for storing information in the cell 850. It is assumed that the transistor element 800A may have threshold voltage VT2a being less compared to threshold voltage VT2b of the transistor element 800B. The generation of different threshold voltages VT2 may readily be achieved during the fabrication of the cell 850 in that, for example, a first implantation sequence is performed so as to form the channel region of the device 800A while the device 800B is masked, and performing a second implantation sequence with the device 800A masked and the device 800B exposed. Other approaches for the generation of different threshold voltages will also be described with reference to FIG. 10.

During the operation of the cell 850, the write and read cycles may be performed as previously described, wherein, when operated at a higher VDD, the transistor element 800B is operated in the self-biasing mode and thus maintains its gate voltage and the gate voltage of the transistor element 800A at the high threshold voltage VT2b when remaining in the high conductivity state. Likewise, when being operated with a low VDD that may range between the threshold VT2b and VT2a of the transistor 800B and the transistor 800A, the device 800A remains in the high-conductivity state and thus keeps the gate voltages of the devices 800A and 800B at the lower threshold voltage VT2a.

It should also be appreciated that more than two devices with different threshold voltages VT2 may be provided in the cell 850, thereby providing the potential for an enhanced functionality. For example, the device 850 may be used to store three different states, one state representing a high impedance state, one state representing a high conductivity state with a gate voltage at the lower threshold voltage VT2a, and one state representing a high conductivity state at the higher threshold voltage VT2b of the device 800B. When writing corresponding states into the cell 850, the bit line has to be pre-charged with respective voltages. Likewise, when more than two transistor elements with different threshold voltages VT2 are provided, a corresponding number of different states may be stored in the cell 850, wherein a single select line 816 and a single bit line 812 is sufficient to address the cell 850 having stored therein a plurality of different states. In other applications, the lower threshold VT2a may be considered as a stand-by threshold, so as to ensure date integrity when the supply voltage VDD decreases below the normal operating voltage due a sleep mode, during which the supply voltage may be delivered by a storage capacitor or the like.

FIG. 9 schematically shows a cross-sectional view of a double channel transistor element 900 in the form of an n-type transistor configured as an SOI device. Thus, the transistor element 900 comprises drain and source regions 904 formed in a semiconductor layer 902 located above an insulation layer 920. The insulation layer 920 may represent a thin dielectric layer formed on any appropriate substrate 901, which is typically a bulk semiconductor substrate such as a silicon substrate. Furthermore, the device 900 comprises a first channel region 903a and a second channel region 903b, which are inversely doped so as to provide the required channel characteristics as previously described. A gate electrode 905 is formed above the channel regions 903a, 903b, and is separated threrefrom by a gate insulation layer 906.

The transistor element 900 may be manufactured in accordance with conventional process techniques, wherein the channel regions 903a, 903b may be formed by ion implantation and/or epitaxial growth techniques, as is previously described with reference to FIG. 3a and FIG. 3b. The SOI device 900 may be advantageously be incorporated into complex microprocessors, which are increasingly fabricated as SOI devices.

FIG. 10 schematically shows a double channel transistor element 1000 comprising a substrate 1001 with a crystalline semiconductor region 1002 formed thereon or therein. Drain and source regions 1004 having a first conductivity type are formed within the regions 1002 so as to form a pn-junction with the remainder of the semiconductor regions 1002, which is doped so as to exhibit a second conductivity type. Between the drain and source regions 1004, a first channel region 1003a and a second region 1003b are formed such that the first channel region 1003a is located more closely to a gate electrode 1005, which is separated from the channel region 1003a by a gate insulation layer 1006. The first channel region 1003a may be doped so as to exhibit the second conductivity type, whereas the second channel region 1003b may exhibit the first conductivity type. In the example illustrated, an n-type double channel transistor is considered. Regarding any threshold voltages VT1 and VT2 (cf. FIGS. 3d and 3e), the same criteria apply as previously explained. Moreover, the first and second channel regions 1003a, 1003b differ from each other in at least one of material composition and internal strain. That is, the characteristics of the respective channel regions may not only be determined by dopant concentration, but also by other parameters such as material composition, internal strain, and the like. For instance, the second channel region 1003b may be comprised of a silicon/germanium composition, which may be formed by epitaxial growth with a subsequent growth of a silicon layer for the first channel region 1003a, wherein, depending on process requirements, the layer 1003b may be relaxed or not so as to have specified internal strain or to impart a specified stress to the layer 1003a. Similarly, the channel region 1003a may be provided as a strained silicon/germanium layer. Also, other materials such as silicon/carbon may be used with appropriate composition in one or both of the channel regions 1003a and 1003b. Thus, the various thresholds VT1 and VT2 for the channel regions 1003a and 1003b may effectively be adjusted by correspondingly selecting a specified material composition and/or a specified internal strain. Since strain engineering becomes more and more important in advanced MOS devices, corresponding process schemes may also advantageously be employed in designing the double channel transistor characteristics. For instance, different threshold voltages may be created at different die regions for the same transistor configuration by locally modifying the strain.

In other embodiments, a specific internal strain in the channel region 1003a and/or 1003b may be created by applying external stress, for instance by means of a specifically stress-containing capping layer enclosing the transistor element 1000. In other embodiments, stress may be created additionally or alternatively by a corresponding implantation of specific ion species, such as hydrogen, helium, oxygen, and the like, in or in the vicinity of the first and second channel regions 1003a, 1003b, thereby specifically adjusting the respective threshold voltages. The adjustment of threshold voltages by stress created by ion implantation is advantageous when a plurality of different threshold voltages have to be created at different die locations or different substrate locations, since respective implantations may readily be performed with different mask schemes in conformity with device requirements.

While FIGS. 9 and 10 illustrate n-type transistor elements 900, 1000, corresponding p-type transistor elements may be provided as well. To this end, the structures shown in FIGS. 9 and 10 may be employed, wherein n-doped areas are replaced with correspondingly p-doped areas and vice versa.

As apparent from the above description of embodiments, there is provided a self-biasing semiconductor device that may mostly advantageously be used in combination with static storage cells, such as RAM cells, so as to significantly reduce the number of transistor elements required. Since already well-established process techniques may be used in forming a corresponding self-biasing transistor element, for instance in the form of a double channel transistor, a significant improvement in bit density and/or performance may be achieved for a given technology node. Moreover, since SRAM devices may now be fabricated in a highly efficient manner with a bit density comparable to dynamic RAM devices, the dynamic devices, usually employed as external operating memory for CPUs, may be readily replaced, thereby providing immense cost and performance advantages. Moreover, the simplified SRAM design of the present invention in combination with a low-cost power supply enables a cost effective utilization of SRAM devices in a wide variety of applications, which may currently employ magnetic storage devices or EEPROMs.

Particularly, double channel field effect transistors are discussed revealing a self-biased stationary state (or “triple state”) between the on and off state. The double channel transistors (DCTs) may be manufactured in standard microelectronic technology, except a special channel doping which causes a parallel channel structure under the gate, as illustrated for instance in FIGS. 3a, 3b, 9 and 10. By this parallel channel structure, also referred to as a double channel, the triple state transfer slope of the transistor is made. According to particular embodiments, the triple state is characterized by a peak in the work function of the transistor (see, e.g., FIGS. 2b, 2d, 4c and 4d). By this peak, the triple state of the double channel transistors is self stabilized and can be used for SRAM cells including only a single double channel transistor and a select transistor. Thus, the discussed transistor elements allow the size of SRAM cells to be reduced by up to 50% since the number of required transistors may be reduced from six to three, or 4 to two for high power SRAM cells. Accordingly, significantly more integrated circuit chips per wafer can be produced. Because of the non-linear work function, the triple state may also be used in oscillators.

Further modifications and variations of the present invention will be apparent to those skilled in the art in view of this description. Accordingly, the description is to be construed as illustrative only and is for the purpose of teaching those skilled in the art the general manner of carrying out the present invention. It is to be understood that the forms of the invention shown and described herein are to be taken as the presently preferred embodiments.

What is claimed is:

1. A static RAM cell comprising:
a storage transistor element for storing a bit of information, comprising:
a p-doped drain region formed in a substantially crystalline semiconductor material;
a p-doped source region formed in said substantially crystalline semiconductor material;
an n-doped channel region located between and adjacent to said drain region and said source region;
a p-doped channel region located between and adjacent to said drain region and said source region and further adjacent to the p-doped channel region; and
a gate electrode to enable control of the n-doped and p-doped channel regions;
a supply voltage terminal connecting said p-doped source region to a supply voltage source providing power to the static RAM cell; and
a conductive region connecting said gate electrode to said supply voltage terminal.

2. The static RAM cell of claim 1, further comprising a select transistor element having a drain terminal, a source terminal and a gate terminal, one of said drain and source terminals connected to said conductive region.

3. The static RAM cell of claim 2, wherein the other of said drain and source terminals is connected to a bit line for writing/reading said bit of information to/from the static RAM cell and said gate electrode is connected to a select line for enabling writing/reading to/from the static RAM cell.

4. The static RAM cell of claim 1, further comprising a ground terminal connecting said p-doped drain region to ground potential.

5. The static RAM cell of claim 1, wherein said storage transistor element further comprises an n-doped semiconductor region located adjacent to said p-doped drain region, said p-doped source region and said p-doped channel region.

6. The static RAM cell of claim 5, further comprising a second conductive region connecting said n-doped semiconductor region to said supply voltage terminal.

7. The static RAM cell of claim 1, wherein said n-doped channel region and said p-doped channel region in combination define a threshold voltage for an abrupt conductivity change of a total conductivity of said n-doped and p-doped channel regions when said total conductivity is in a low impedance state.

8. The static RAM cell of claim 7, wherein said abrupt conductivity change defines a local maximum of said total conductivity with respect to an absolute amount of gate voltage applied to said gate electrode.

9. The static RAM cell of claim 1, wherein said n-doped channel region and said p-doped channel region are configured to self-bias said gate electrode, thereby causing the storage transistor element to enter a stationary conductive state.

10. A static RAM cell comprising:
a first storage transistor element for storing a bit of information, comprising:
a first drain region formed in a substantially crystalline semiconductor material and n-doped;
a first source region formed in said substantially crystalline semiconductor material and n-doped;
an first channel region, p-doped and located between and adjacent to said first drain region and said first source region;
a second channel region, n-doped and located between and adjacent to said first drain region and said first source region and further adjacent to the first channel region; and
a first gate electrode to enable control of the first and second channel regions;
a second storage transistor element for storing said bit of information, comprising:
an second drain region formed in said substantially crystalline semiconductor material and p-doped;
an second source region formed in said substantially crystalline semiconductor material and p-doped;
a third channel region, n-doped and located between and adjacent to said second drain region and said second source region;
a fourth channel region, p-doped and located between and adjacent to said second drain region and said second source region and further adjacent to the third channel region; and
a second gate electrode to enable control of the third and fourth channel regions; and
a conductive region connecting said first source region, said second source region, said first gate electrode and said second gate electrode.

11. The static RAM cell of claim 10, further comprising a select transistor element having a drain terminal, a source terminal and a gate terminal, one of said drain and source terminals connected to said conductive region.

12. The static RAM cell of claim 11, wherein the other of said drain and source terminals is connected to a bit line for writing/reading said bit of information to/from the static RAM cell and said gate electrode is connected to a select line for enabling writing/reading to/from the static RAM cell.

13. The static RAM cell of claim 10, further comprising a supply voltage terminal connecting said first drain region to a supply voltage source providing power to the static RAM cell.

14. The static RAM cell of claim 13, wherein said second storage transistor element further comprises an n-doped semiconductor region located adjacent to said second drain region, said second source region and said forth channel region.

15. The static RAM cell of claim 14, further comprising a second conductive region connecting said n-doped semiconductor region to said supply voltage terminal.

16. The static RAM cell of claim 10, further comprising a ground terminal connecting said second drain region to ground potential.

17. The static RAM cell of claim 16, wherein said first storage transistor element further comprises a p-doped semiconductor region located adjacent to said first drain region, said first source region and said second channel region.

18. The static RAM cell of claim 17, further comprising a third conductive region connecting said p-doped semiconductor region to said ground terminal.

19. A computer-readable medium comprising computer-executable instructions which, when executed by a computing system, cause the computing system to simulate the behavior of a static RAM cell, the computer-executable instructions comprising:
instructions for simulating a field effect transistor having a drain terminal, a source terminal and a gate terminal;
instructions for simulating a first voltage controlled switch connected to one of said drain and source terminals; and
instructions for simulating a second voltage controlled switch connected said first voltage controlled switch and the other of said drain and source terminals.

20. The computer-readable medium of claim 19, further comprising computer-executable instructions for simulating a resistor connected between said one of said drain and source terminals and said gate terminal.
